(19) United States
(12) Patent Application Publication
(10) Pub. No.: US 2013/0076383 A1
(43) Pub. Date: Mar. 28, 2013

(54) METHOD FOR TESTING AN INTEGRATED CIRCUIT

(71) Applicants: Peter Poinstingl, Zwettl (AT); Christoph Knaupp, Wiener Neustadt (DE); Helmut Randoll, Vaihingen (DE); Ralf Kraemer, Kustadingen (DE); Thomas Wieja, Gomaringen (DE); Steffen Wirth, Stuttgart (DE); Stefan Doehren, Remshalden-Grunbach (DE); Thomas Braun, Stuttgart (DE)

(72) Inventors: Peter Poinstingl, Zwettl (AT); Christoph Knaupp, Wiener Neustadt (DE); Helmut Randoll, Vaihingen (DE); Ralf Kraemer, Kustadingen (DE); Thomas Wieja, Gomaringen (DE); Steffen Wirth, Stuttgart (DE); Stefan Doehren, Remshalden-Grunbach (DE); Thomas Braun, Stuttgart (DE)

(21) Appl. No.: 13/582,331

(22) PCT Filed: Feb. 7, 2011
(86) PCT No.: PCT/EP2011/051706

§ 371 Date: Dec. 11, 2012

(30) Foreign Application Priority Data
Mar. 1, 2010 (DE) 102010002460.0

(51) Int. Cl. G01R 31/28

(52) U.S. Cl. CPC G01R 31/2884
USPC 324/750.3

(57) ABSTRACT

A method for testing an integrated circuit and an integrated circuit. The integrated circuit has an internal testing structure which may be accessed via an internal test access port and a control bus which is conducted to the outside via control ports, it being possible to switch over between a running mode and a test mode so that, in the test mode, the test access port is accessed via the control ports and the control bus, thus testing the integrated circuit.

### FIELD OF THE INVENTION

The present invention relates to a method for a, in particular, non-destructive testing of an integrated circuit which is installed on a printed circuit board, for example. For this purpose, the circuitry of the integrated circuit is prepared according to the present invention. The present invention further relates to such an integrated circuit which is, in particular, provided to carry out the method.

### BACKGROUND INFORMATION

Integrated circuits (ICs) which are, for example, used in control units of motor vehicles are tested in an unpackaged state via IC-internal testing structures in so-called built-in self-tests during the IC manufacture. For this purpose, a comprehensive testing structure is integrated into the IC in which every point of the circuit may be reached and tested via internal bus systems starting from a test access port (TAP). For the test, this testing structure is contacted with the aid of needle adapters. After the test, the ICs are packaged, i.e., cast in a housing, so that the TAP is no longer accessible for other tests.

To obtain a diagnosis, it is nowadays customary to unsolder an IC from the control unit, the control unit being destroyed in the process, and to test its functions on an IC tester. Due to the high number of combinatory states, the test depth thus achievable is not very high. Due to the ever smaller structures, the unsoldering is increasingly associated with the risk of the test specimen being destroyed.

Another diagnostic step requires milling open the IC and contacting the TAP. The complexity of this procedure is high and the risk of the test specimen being destroyed is also high. With the aid of the described method, the ICs are tested in the integrated state without running the risk of being destroyed.

Here, it is conventional to conduct the TAP of all ICs in a circuit to the outside with the aid of additional contacts on every IC and to connect them on the printed circuit board via a separate bus system to a computer which is able to control these IC tests. This, however, results in every IC costing more due to the contacts as well as due to the additional printed conductors so that this method is out of the question for large-scale production.

Therefore, it should be achieved that the IC tests also work in the integrated state, i.e., when the IC is integrated into the control unit and the control unit is installed into the vehicle. Moreover, it should be achieved that testability is provided without the need of an additional test bus in the control unit, which is associated with corresponding costs, e.g., due to an additional printed conductor surface and connecting pins.

### SUMMARY

Against this background, an example method for testing an integrated circuit and an integrated circuit are provided.

With the aid of the described example method, it is possible to carry out an IC test even in the integrated state. No additional test bus is necessary.

It is understood that the above-named features and the features explained below are usable not only in the particular given combination, but also in other combinations or individually, without departing from the scope of the present invention.

### BRIEF DESCRIPTION OF THE DRAWINGS

FIG. 1 shows a conventional integrated circuit.

FIG. 2 shows one specific embodiment of an example circuit in accordance with the present invention.

FIG. 3 shows the example circuit from FIG. 2 during a test in the semiconductor plant.

FIG. 4 shows the example circuit from FIG. 2 when controlled in the control unit.

FIG. 5 shows the example circuit from FIG. 2 during a test according to the present invention in the integrated state.

### DETAILED DESCRIPTION OF EXAMPLE EMBODIMENTS

The present invention is illustrated schematically on the basis of specific example embodiments shown in the figures and described in greater detail below.

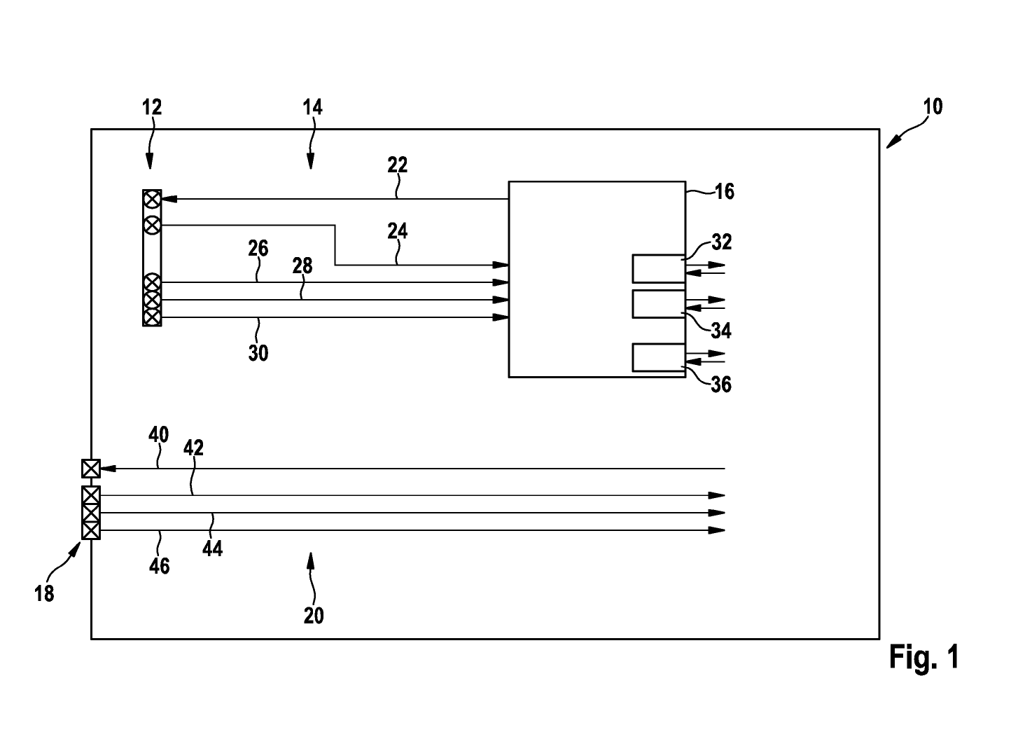

FIG. 1 shows a wiring diagram of a conventional integrated circuit, denoted with reference numeral 10 as a whole. As shown, test contact surfaces or test pads 12 which are connected to a test access port or TAP 16 via a test bus 14.

Furthermore, FIG. 1 shows input/output pins (IO pins) as control ports 18 which are connected to a control bus 20.

The individual lines of test bus 14 are provided for signals, namely TDO 22, TRST 24, TCK 26, TMS 28, and TDI 30. TAP 16 has n input/output ports, namely DR_1 32 for test data, DR_2 34 for a set-up, a stimulation, and an observation, as well as DR_n 36 (as shown).

The lines of control bus 20 are also provided for signals, namely SO 40, SI 42, CS 44, and CLK 46.

Test bus 14 and control bus 20 are separate from one another in circuit 10 shown in FIG. 1. In the semiconductor plant, test bus 14 is accessible only in unpackaged circuit 10. This is where circuit 10 is tested and cast into a package so that no test may be carried out afterwards. Only control bus 20 is conducted to the outside via pins 18 as a connection between circuit 10 and a microprocessor.

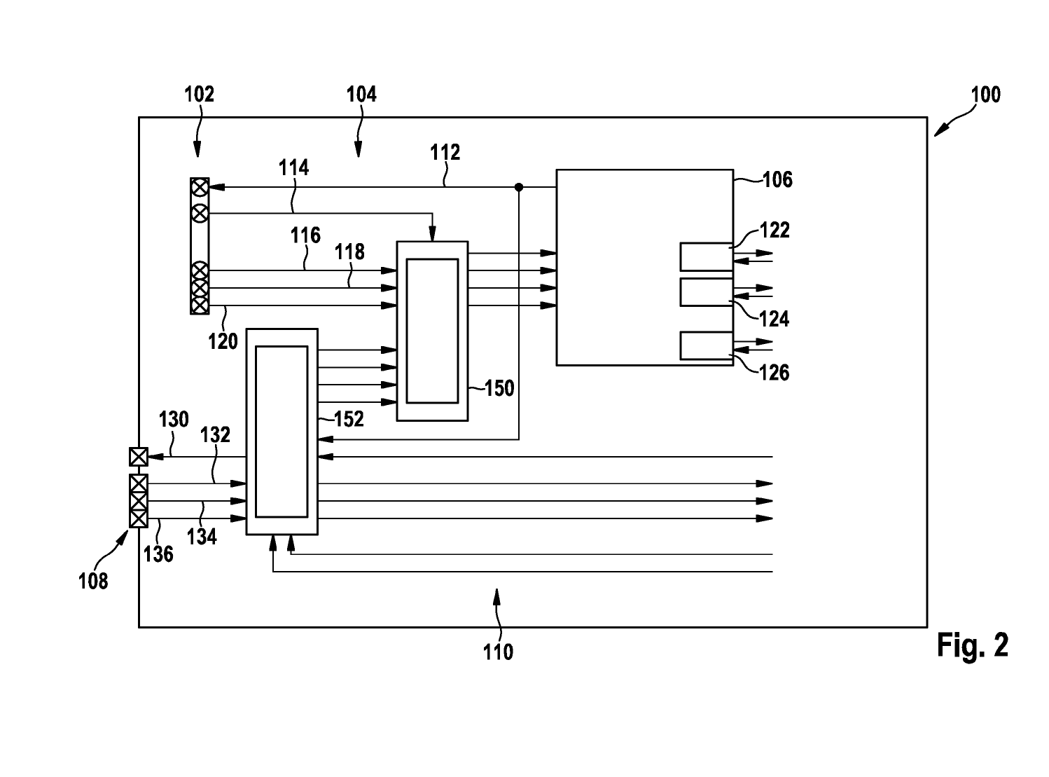

FIG. 2 shows a wiring diagram of an integrated circuit, denoted with reference numeral 100 as a whole. The illustration shows test contact surfaces or test pads 102 which are connected to a test access port or TAP 106 via a test bus 104.

Furthermore, FIG. 2 shows input/output pins (IO pins) as control ports 108 which are connected to a control bus 110.

The individual lines of test bus 104 are provided for signals, namely TDO 112, TRST 114, TCK 116, TMS 118, and TDI 120. TAP 106 has n input/output ports, namely DR_1 122 for test data, DR_2 124 for a set-up, a stimulation, and an observation, as well as DR_n 126 (as illustrated).

The lines of control bus 110 are also provided for signals, namely SO 130, SI 132, CS 134, and CLK 136.

By inserting a multiplex circuit 150 and 152, it is achieved that circuit 100 works as before.

To save housing pins, the SPI pins are conducted to TAP (test access port) 106 via multiplexer 150 and 152. Multiplexer 150 and 152 is activated via a locking mechanism. This locking mechanism is defined by a special SW key as well as by the use of a special sequence control.

The locking mechanism may be operated with the aid of SW keys to switch over between a running mode and a test mode.

After activating the multiplexer, the SPI pins physically available on the ASIC housing are mapped on the internal test interface. In this exemplary embodiment, the multiplexer is switched as follows when activated by the locking mechanism mentioned previously:

### SO=>TDO

### SI=>TDI

### SCK=>TCK

### CS=>TMS

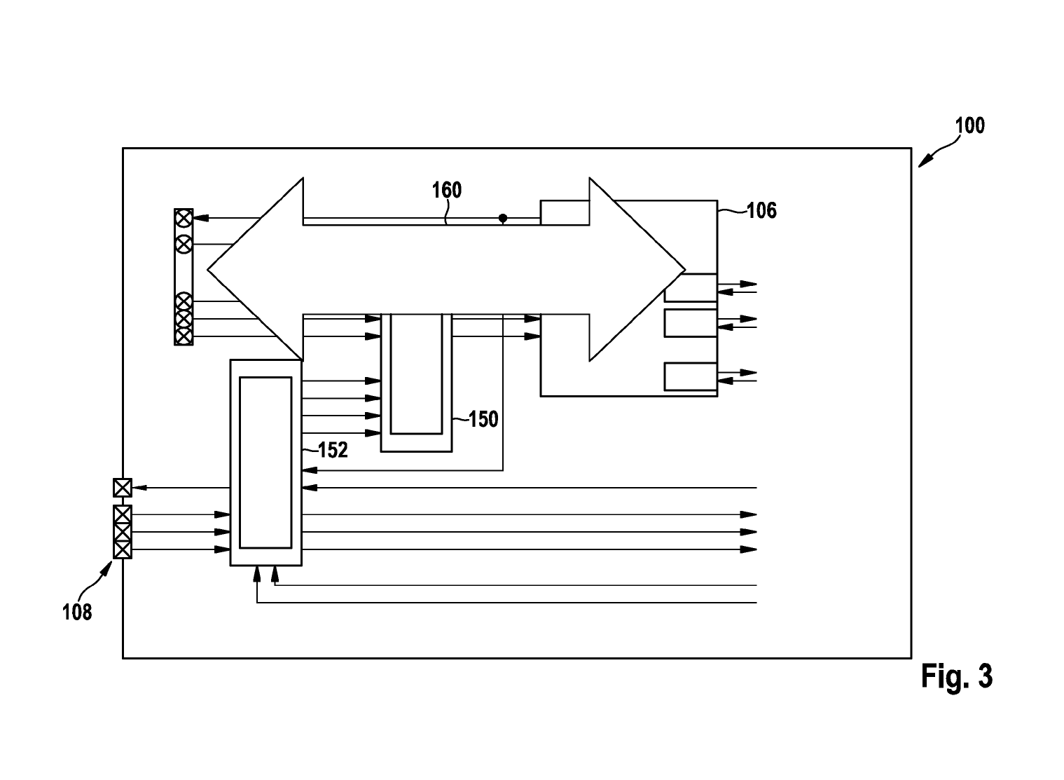

FIG. 3 shows circuit 100 from FIG. 2, an arrow 160 illustrating that a test may be carried out in the semiconductor plant as before.

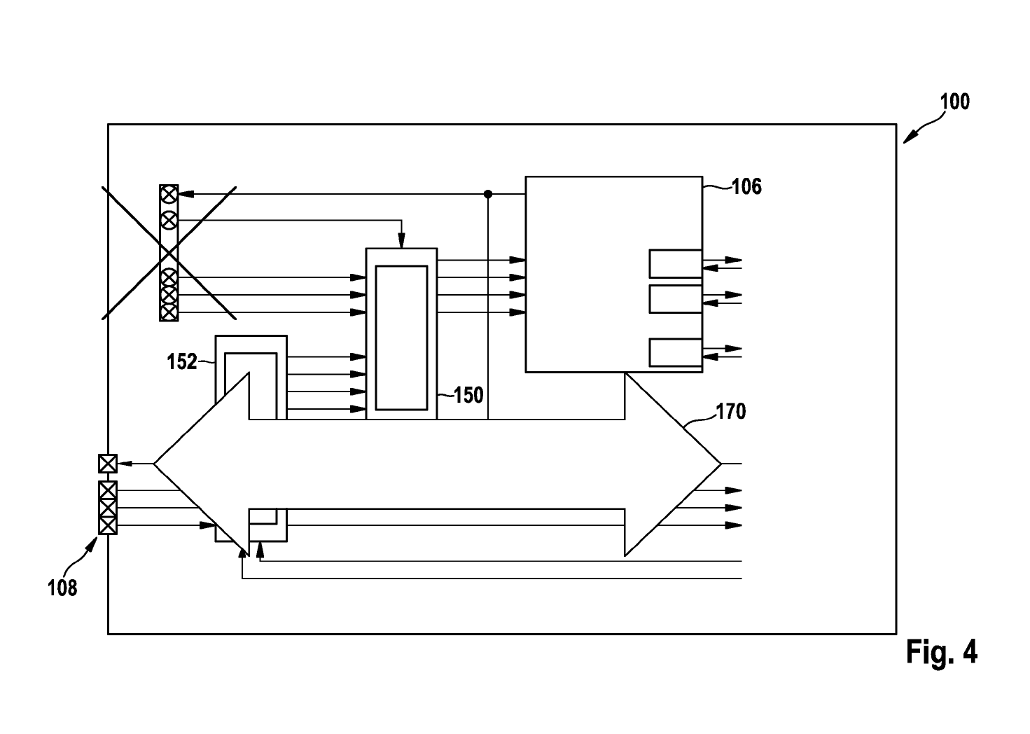

FIG. 4 shows circuit 100, an arrow 170 illustrating that circuit 100 may be controlled in a control unit as before.

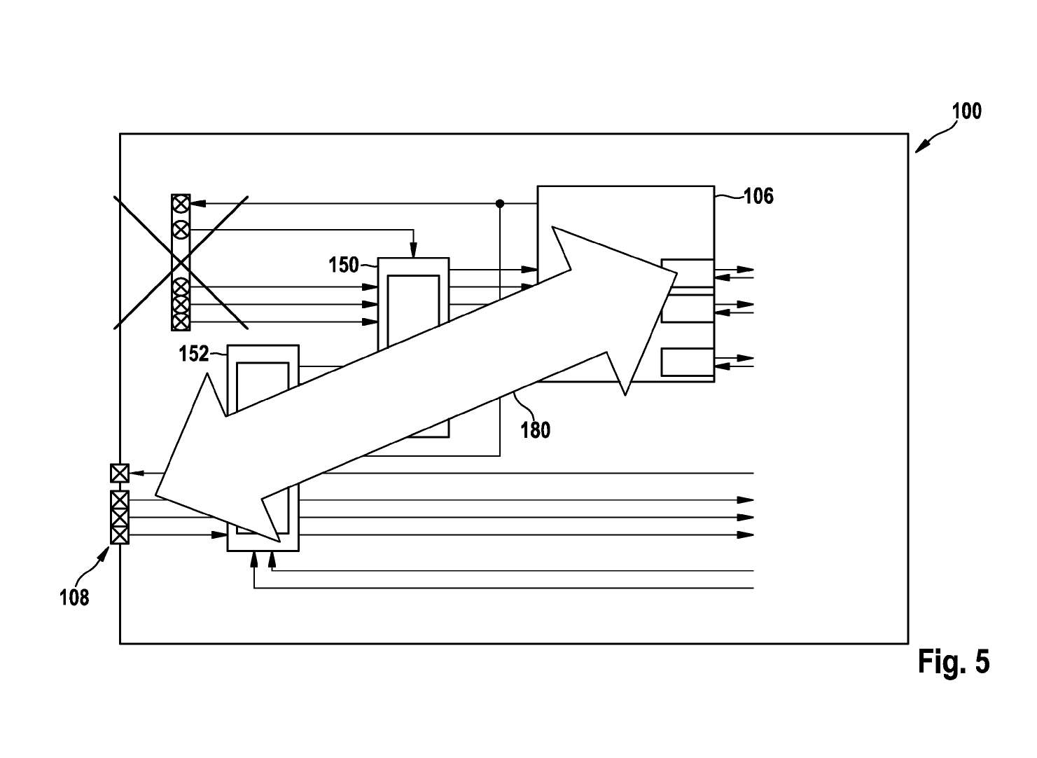

FIG. 5 shows circuit 100 together with the presented additional usage. An arrow 180 shows how IC-internal TAP 106 may be controlled by the microprocessor via the bus system present in the control unit so that the IC-internal test may be carried out.

Here, a differentiation should be made on whether the control unit is in the running mode according to FIG. 4 or whether the control unit is being tested in a repair shop according to FIG. 5. A locking mechanism may be used for this purpose.

This locking mechanism may distinguish itself in that it must be carried out in a defined sequence control.

The present invention thus enables a self-test of circuit 100, without the need of having a separate test bus.

1-9. (canceled)

10. A method for testing an integrated circuit having an internal testing structure which may be accessed via an internal test access port and having a control bus which is conducted to an outside via control ports, the method comprising:
switching over between a running mode and a test mode; and
accessing, in the test mode, the test access port via the control ports and the control bus to test the integrated circuit;
wherein the switching over between the running mode and the test mode is performed using a multiplexer, and a switch-over to the test mode being caused by entering a software key.

11. The method as recited in claim 10, further comprising:
locking, using a locking mechanism, to switch over between the running mode and the test mode.

12. An integrated circuit having an internal testing structure which may be accessed via an internal test access port and having a control bus which is conducted to an outside via control ports, the integrated circuit being configured to switch over between a running mode and a test mode so that, in the test mode, the test access port is accessed via the control ports and the control bus, the integrated circuit including a multiplexer to switch over between the running mode and the test mode, the integrated circuit being configured to switch-over to the test mode by entry of a software key.

13. The integrated circuit as recited in claim 12, wherein the control bus is an SPI bus.

14. The integrated circuit as recited in claim 12, further comprising:
a locking mechanism which causes a switch-over between the running mode and the test mode.

15. The integrated circuit as recited in claim 10, further comprising:
an internal test bus to provide access to the test access port.
